(19) United States
(12) Patent Application Publication
(10) Pub. No.: US 2013/0320810 A1
(43) Pub. Date: Dec. 5, 2013

(54) Piezoelectric Vibrating Component

(71) Applicant: Murata Manufacturing Co., Ltd., Nagaokakyo-Shi (JP)

(72) Inventors: Susumu Okazaki, Nagaokakyo-Shi (JP); Masakazu Yamauchi, Nagaokakyo-Shi (JP)

(21) Appl. No.: 13/934,376

(22) Filed: Jul. 3, 2013

Related U.S. Application Data
(63) Continuation of application No. PCT/JP2011/075392, filed on Nov. 4, 2011.

(30) Foreign Application Priority Data
Jan. 14, 2011 (JP) 2011-006171

(51) Int. Cl. H01L 41/053

(52) U.S. Cl. CPC H01L 41/053
USPC 310/345

(57) ABSTRACT

A piezoelectric vibrating component that includes a plate-shaped seat having first and second opposed surfaces, and a piezoelectric diaphragm attached to the first surface. The piezoelectric diaphragm has an expansion vibration mode as a main vibration mode. The piezoelectric vibrating component is used with the second surface of the seat attached to a vibrated body. The seat is structured so that the piezoelectric vibrating component entirely vibrates in the expansion vibration mode as the main vibration mode when the piezoelectric diaphragm vibrates.

### CROSS REFERENCE TO RELATED APPLICATIONS

The present application is a continuation of International application No. PCT/JP2011/075392, filed Nov. 4, 2011, which claims priority to Japanese Patent Application No. 2011-006171, filed Jan. 14, 2011, the entire contents of each of which are incorporated herein by reference.

### FIELD OF THE INVENTION

The present invention relates to a piezoelectric vibrating component such as a piezoelectric actuator or a piezoelectric sound component.

### BACKGROUND OF THE INVENTION

Conventionally, piezoelectric vibrating components, such as a piezoelectric actuator and a piezoelectric sound component, are widely used as an actuator and a sound component. The piezoelectric vibrating components are also used as a vibration source for producing sound from a panel (vibrated body) by vibrating the panel and a sensor for sensing vibration. As an example of such a piezoelectric vibrating component, for example, Patent Document 1 described below proposes a piezoelectric actuator including a piezoelectric element that performs expansion and contraction vibration, and a seat with one surface to which the piezoelectric element attached. Patent Document 1 describes that the seat in the piezoelectric actuator has a function of converting expansion and contraction vibration of the piezoelectric element into flexural vibration.

Patent Document 1: Domestic Re-publication of PCT International Publication for Patent Application No. 2007/083497

### SUMMARY OF THE INVENTION

However, when the piezoelectric actuator described in the above Patent Document 1 is used to vibrate while being attached to the vibrated body, the displacement amount of the vibrated body cannot be sufficiently increased, and therefore, it is difficult to obtain sufficient output.

The present invention has been made in view of such a point, and provides a piezoelectric vibrating component with large displacement amount.

A piezoelectric vibrating component according to the present invention includes a plate-shaped seat having first and second principal surfaces, and a piezoelectric diaphragm attached to the first principal surface and having an expansion vibration mode as a main vibration mode, and is used with the second principal surface of the seat being attached to a vibrated body. The seat is structured so that the piezoelectric vibrating component entirely vibrates in an expansion vibration mode as a main vibration mode when the piezoelectric diaphragm vibrates.

In a specific aspect of the piezoelectric vibrating component of the present invention, an elastic modulus of the seat is within a range of 1/600 to 1 times an elastic modulus of the piezoelectric diaphragm. According to this structure, the piezoelectric vibrating component itself continues vibration so that expansion vibration is dominant. When the piezoelectric vibrating component is attached to the vibrated body, the vibrated body performs flexural vibration. For this reason, the vibration transmission efficiency to the vibrated body is made higher than when a piezoelectric vibrating component that performs flexural vibration is attached. As a result, a larger displacement amount can be obtained.

In another specific aspect of the piezoelectric vibrating component of the present invention, the piezoelectric vibrating component further includes an adhesive layer that bonds the seat and the piezoelectric diaphragm.

In a further specific aspect of the piezoelectric vibrating component of the present invention, the seat is formed of resin, and a thickness of the seat is within a range of 0.01 mm to 5.0 mm.

According to the present invention, it is possible to provide a piezoelectric vibration component with large displacement amount.

### BRIEF DESCRIPTION OF THE DRAWINGS

FIG. 1 is a schematic plan view of a piezoelectric vibrating component according to an embodiment of the present invention.

FIG. 2 is a schematic cross-sectional view, taken along line II-II of FIG. 1.

FIG. 3 is a graph demonstrating the relationship between the ratio of the elastic modulus of a seat to the elastic modulus of a piezoelectric diaphragm, and the displacement amount of a vibrated body to which the piezoelectric vibrating component is attached.

### DESCRIPTION OF THE PREFERRED EMBODIMENTS

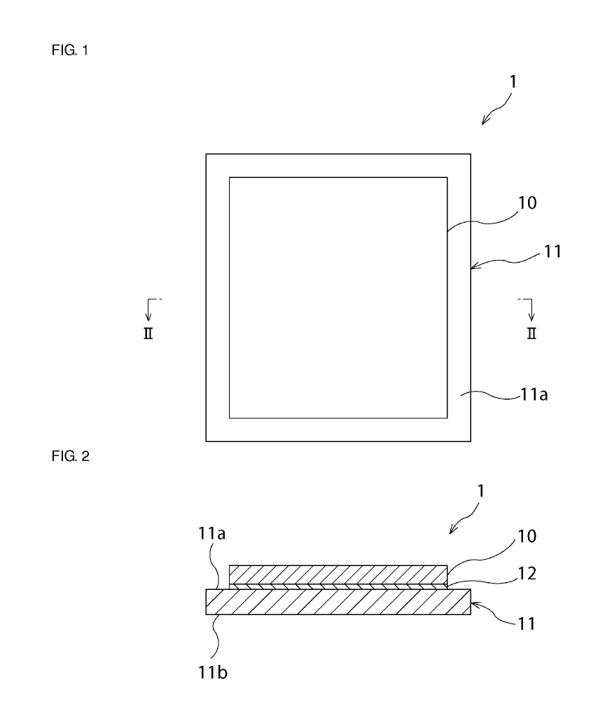

A preferred embodiment of the present invention will be described below by giving a piezoelectric vibrating component 1 illustrated in FIGS. 1 and 2 as an example. However, the piezoelectric vibrating component 1 is just exemplary. A piezoelectric vibrating component of the present invention is not limited to the piezoelectric vibrating component 1.

FIG. 1 is a schematic plan view of the piezoelectric vibrating component of the embodiment. FIG. 2 is a schematic cross-sectional view, taken along line II-II of FIG. 1. The piezoelectric vibrating component 1 illustrated in FIGS. 1 and 2 is used while being mounted on a vibrated body, and functions, for example, as a piezoelectric actuator or a piezoelectric sound component.

The piezoelectric vibrating component 1 includes a plate-shaped seat 11. The seat 11 has first and second principal surfaces 11a and 11b. The piezoelectric vibrating component 1 is used while the second principal surface 11b of the seat 11 is attached to the vibrated body.

The material of the seat 11 is not particularly limited. For example, the seat 11 can be formed of resin such as polyethylene, Teflon (registered trademark), nylon, or PET, glass-epoxy resin, or low-rigidity metal such as aluminum or tin. The thickness of the seat 11 is also not particularly limited. The thickness of the seat 11 can be, for example, about 0.01 mm to 5.0 mm.

A piezoelectric diaphragm 10 is attached to the first principal surface 11a of the seat 11. While an attachment method for the piezoelectric diaphragm 10 is not particularly limited, the piezoelectric diaphragm 10 is attached by being bonded to the first principal surface 11a with an adhesive layer 12 in the embodiment. For example, the adhesive layer 12 can be formed of an epoxy resin adhesive.

The piezoelectric diaphragm 10 includes a piezoelectric substrate, and a pair of electrodes for applying voltage to the piezoelectric substrate. The piezoelectric diaphragm 10 has an expansion vibration mode as a main vibration mode in a single state in which it is not fixed to the seat 11. That is, the piezoelectric substrate is polarized such that the main vibration mode of the piezoelectric diaphragm 10 is an expansion vibration mode.

For example, the piezoelectric substrate can be formed of lead zirconate titanate (PZT). The electrodes can be formed of metal such as Ag, Cu, Al, Au, Pt, or Pd, or an alloy containing one or more of these metals.

In the embodiment, the seat 11 is structured so that the piezoelectric vibrating component 1 entirely vibrates in an expansion vibration mode as a main vibration mode when the piezoelectric diaphragm 10 vibrates in an expansion vibration mode as a main vibration mode. More specifically, in the embodiment, the elastic modulus of the seat 11 is within the range of 1/600 to 1 times the elastic modulus of the piezoelectric diaphragm 10. When this piezoelectric diaphragm 10 is attached to the seat 11 having an elastic modulus lower than that of the piezoelectric diaphragm 10, the piezoelectric vibrating component 1 maintains dominance of the expansion vibration mode. When the piezoelectric vibrating component 1 is attached to the vibrated body, the vibrated body performs flexural vibration. Hence, the transmission efficiency of vibration energy to the vibrated body is made higher than when a piezoelectric vibrating component that performs flexural vibration is attached. Therefore, for example, a piezoelectric sound component having high sound pressure and a piezoelectric actuator having large driving force can be obtained by using the piezoelectric vibrating component 1 of the embodiment.

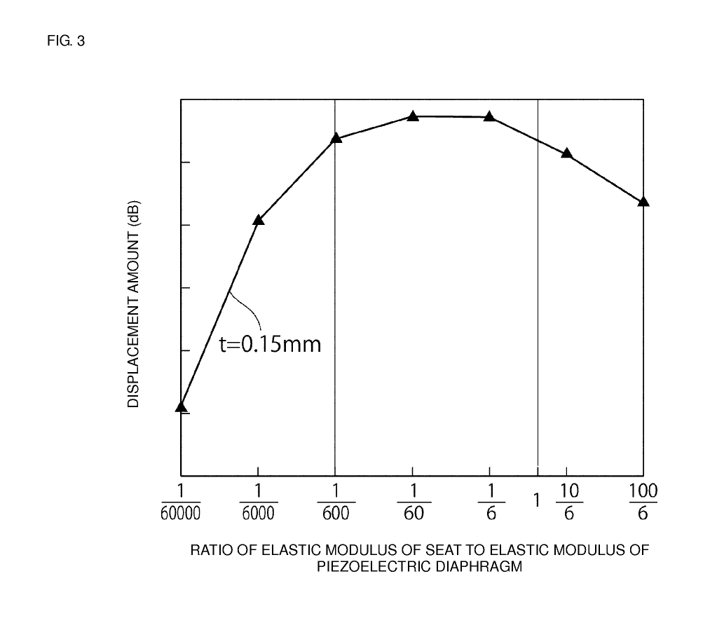

This effect will be described in more detail below. FIG. 3 is a graph demonstrating the relationship between the ratio of the elastic modulus of the seat 11 to the elastic modulus of the piezoelectric diaphragm 10, and the displacement amount of the vibrated body to which the piezoelectric vibrating component 1 is attached. FIG. 3 shows that an obtained displacement amount is small when the elastic modulus of the seat 11 is higher than the elastic modulus of the piezoelectric diaphragm 10. This is considered to be because, since the seat 11 restricts the vibration of the piezoelectric diaphragm 10 and the main vibration mode of the piezoelectric vibrating component becomes a flexural vibration mode, when the piezoelectric vibrating component is attached to the vibrated body, loss is caused in energy transmission from the piezoelectric vibrating component to the vibrated body. That is, this is considered to be because, when the elastic modulus of the seat 11 is higher than the elastic modulus of the piezoelectric diaphragm 10 and the main vibration mode is the flexural vibration mode, the transmission loss of the vibration energy to the vibrated body increases, and this decreases the displacement amount of the vibrated body. More specifically, the main vibration mode is a flexural vibration mode in samples in which the ratio of the elastic modulus of the seat 11 to the elastic modulus of the piezoelectric diaphragm ((elastic modulus of the seat 11)/(elastic modulus of the piezoelectric diaphragm 10)) is 10/6 and 100/6.

In contrast, when the elastic modulus of the seat 11 is lower than the elastic modulus of the piezoelectric diaphragm 10, since vibration is not drastically restricted by the seat 11, the main vibration mode is an expansion vibration mode. Since the piezoelectric vibrating component 1 does not perform flexural vibration by itself in this state, it does not function as an actuator or a sound component. However, when the vibrated body is subjected to flexural vibration while the piezoelectric vibrating component is attached thereto, the transmission efficiency of vibration energy from the piezoelectric vibrating component is enhanced. As a result, the displacement amount of the vibrated body can be increased further. That is, it is conceivable that a great displacement amount of the vibrated body can be obtained by structuring the seat 11 so that the main vibration mode becomes an expansion vibration mode. More specifically, the main vibration mode is an expansion vibration mode in samples in which the ratio of the elastic modulus of the seat 11 to the elastic modulus of the piezoelectric diaphragm is ⅙, 1/60 and 1/600.

However, when the elastic modulus of the seat 11 is excessively lower than the elastic modulus of the piezoelectric diaphragm 10, the displacement amount sometimes decreases, as illustrated in FIG. 3. This is considered to be because the seat 11 is too soft and vibration of the piezoelectric diaphragm 10 is not properly transmitted to the vibrated body. As the above results show, to obtain a larger displacement amount, the elastic modulus of the seat 11 is preferably within the range of 1/600 to 1 times the elastic modulus of the piezoelectric diaphragm 10.

### REFERENCE SIGNS LIST

1 piezoelectric vibrating component

10 piezoelectric diaphragm

11 seat

11a first principal surface

11b second principal surface

12 adhesive layer

1. A piezoelectric vibrating component comprising:
a plate-shaped seat having first and second opposed surfaces; and
a piezoelectric diaphragm attached to the first surface and having an expansion vibration mode as a main vibration mode,
wherein the second surface of the seat is configured to be attached to a vibrated body, and
wherein the seat is structured so that the piezoelectric vibrating component entirely vibrates in the expansion vibration mode as the main vibration mode when the piezoelectric diaphragm vibrates.

2. The piezoelectric vibrating component according to claim 1, wherein an elastic modulus of the seat is within a range of 1/600 to 1 times an elastic modulus of the piezoelectric diaphragm.

3. The piezoelectric vibrating component according to claim 1, further comprising an adhesive layer that bonds the seat and the piezoelectric diaphragm.

4. The piezoelectric vibrating component according to claim 1, wherein the seat is a resin seat.

5. The piezoelectric vibrating component according to claim 4, wherein a thickness of the seat is within a range of 0.01 mm to 5.0 mm. (based on claim 4)

6. The piezoelectric vibrating component according to claim 1, wherein a thickness of the seat is within a range of 0.01 mm to 5.0 mm. (based on claim 4)

7. The piezoelectric vibrating component according to claim 1, wherein a material of the seat is selected from the group consisting of polyethylene, Teflon, nylon, PET, glass-epoxy resin, aluminum and tin. (based on paragraph [0015])

8. The piezoelectric vibrating component according to claim 1, wherein a ratio of an elastic modulus of the seat to an elastic modulus of the piezoelectric diaphragm is such that the piezoelectric vibrating component entirely vibrates in the expansion vibration mode as the main vibration mode when the piezoelectric diaphragm vibrates. (based on paragraph [0024])

9. The piezoelectric vibrating component according to claim 8, wherein the ratio is ⅙. (based on paragraph [0024])

10. The piezoelectric vibrating component according to claim 8, wherein the ratio is 1/60. (based on paragraph [0024])

11. The piezoelectric vibrating component according to claim 8, wherein the ratio is 1/600. (based on paragraph [0024])
